(19) United States
(12) Patent Application Publication
(10) Pub. No.: US 2009/0256622 A1
(43) Pub. Date: Oct. 15, 2009

(54) SOFT THERMAL FAILURE IN A HIGH CAPACITY TRANSMISSION SYSTEM

(75) Inventor: Kim B. ROBERTS, Nepean (CA)

Correspondence Address: BLAKE, CASSELS & GRAYDON, LLP, 45 O'CONNOR ST., 20TH FLOOR, OTTAWA, ON, K1P 1A4, CA

(73) Assignee: NORTEL NETWORKS LIMITED, St. Laurent (CA)

(21) Appl. No.: 12/101,209

(22) Filed: Apr. 11, 2008

(51) Int. Cl. H01L 35/00

(52) U.S. Cl. 327/512

(57) ABSTRACT

A method of managing operation of an Integrated Circuit (IC) designed to process a signal A temperature of the IC is detected, and signal processing performed by the IC adjusted based on the detected temperature.

### CROSS-REFERENCE TO RELATED APPLICATIONS

This is the first application filed in respect of the present invention.

### TECHNICAL FIELD

The present invention relates to high-speed communications networks, and in particular to methods and systems for soft thermal failure in a high capacity transmission system.

### BACKGROUND OF THE INVENTION

In the field of communications networks, telecommunications equipment is required to meet stringent availability and environmental requirements. In very general terms, telecommunications equipment (such as transmitters, receivers, routers and switches) must be able to function properly under any anticipated environmental conditions. For example, the Synchronous Optical Network (SONET) standard specifies that an OC-192 signal operate at a line rate of 9.95328 Gb/s (giga-bits/second) with a maximum permissible bit error rate (of 10-12). All SONET equipment designed to process such a signal must be able to achieve this level of performance, even in the presence of simultaneous events such as worst case ambient air temperatures, fan failures, dusty filters, thin air at a high altitude location, worst case device processing, and worst case power supply voltages. Other network protocols provide different line rates and maximum permissible error rates, but in all cases, the installed equipment must meet the specified performance under anticipated worst-case conditions. It will also be noted that, at the physical network layer, the data rate (line rate) is generally fixed and all data bits in the signal must be processed.

As is well known in the art, Integrated Circuit (IC) components have a maximum safe operating temperature. For example a CMOS chip may operate with a junction temperature of 100° C. Above that temperature, timing and signal errors can occur such that the chip may temporarily fail to perform its function, and the probability of permanent chip failure also increases.

The heat generated in semiconductor circuits (such as CMOS) is the combined effect of leakage currents and state transitions due to signal processing. Leakage currents are present any time power is supplied to the circuit, so that, even when the circuit is not processing a signal, a base level of heat will always be generated within the circuit. The active processing of a signal involves state transitions within the logic gates forming the circuit, and the resulting currents produce an “active” heating of the circuit. The magnitude of this active heating is approximately proportional to the frequency of the clock applied to the circuit. Thus, all other things being equal, doubling the clock speed will double the active heating of the circuit.

In high capacity telecommunications systems, clock speeds of 20 GHz and higher are commonly encountered. At these speeds, the amount of active heat generated in an IC can amount to several Watts, which can easily raise junction temperatures to dangerous levels. This problem is expected to become increasingly severe due to continuing demand for ever faster channel line rates (and thus IC clock speeds)

Accordingly, techniques that enable reliable operation of IC components in a high capacity telecommunications systems are highly desirable.

### SUMMARY OF THE INVENTION

The present invention addresses the above-noted problems by providing a technique for soft thermal failure in a high speed IC.

Thus, an aspect of the present invention provides a method of managing operation of an Integrated Circuit (IC) designed to process a signal. A temperature of the IC is detected, and signal processing performed by the IC adjusted based on the detected temperature.

### BRIEF DESCRIPTION OF THE DRAWINGS

Further features and advantages of the present invention will become apparent from the following detailed description, taken in combination with the appended drawings, in which:

FIG. 1 is a block diagram schematically illustrating principal elements and operations of a coherent optical receiver in which embodiments of the present invention may be implemented;

FIG. 2 is a block diagram schematically illustrating principal elements and operations of an equalizer usable in the optical receiver of FIG. 1;

FIG. 3 is a block diagram schematically illustrating principal elements and operations of a retiming block usable in the equalizer of FIG. 2;

FIG. 4 is a block diagram schematically illustrating a technique for zeroing-out Least Significant Bits (LSBs) of the multi-bit samples generated by each A/D converter of the optical receiver of FIG. 1;

FIG. 5 is a block diagram schematically illustrating a technique for zeroing-out LSBs of the multi-bit tap values generated by each Fast Fourier Transform (FFT) block of the equalizer of FIG. 2;

FIG. 6 is a block diagram schematically illustrating a technique for controlling an impulse response of each Fast Fourier Transform (FFT) block of the equalizer of FIG. 2;

FIG. 7 is a block diagram schematically illustrating a technique for controlling a number of Forward Error Correction decoding iterations; and

FIG. 8 is a block diagram schematically illustrating a technique for controlling a number of parallel Forward Error Correction decoding iterations.

It will be noted that throughout the appended drawings, like features are identified by like reference numerals.

### DETAILED DESCRIPTION OF THE PREFERRED EMBODIMENT

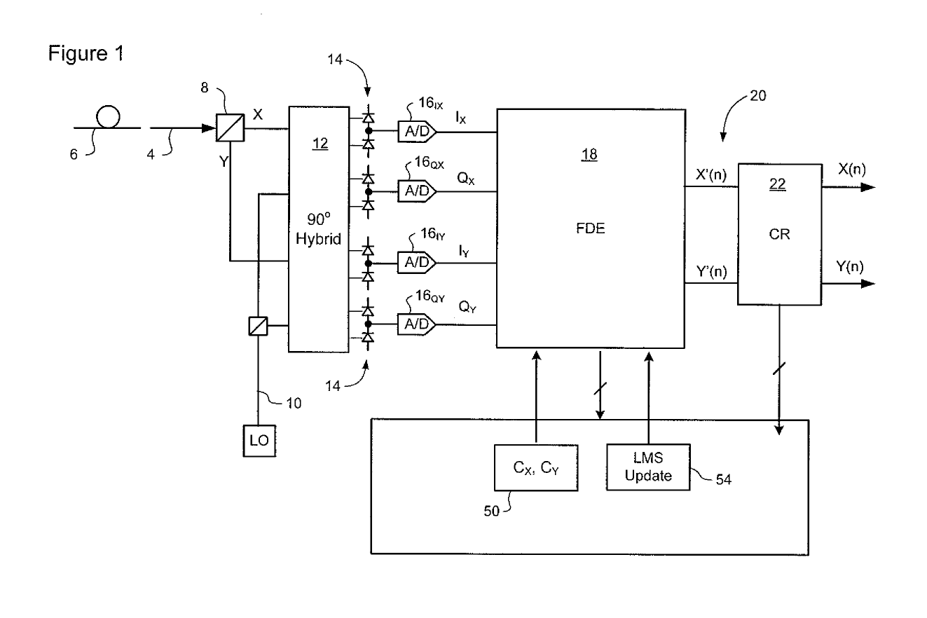

The present invention provides technique for soft thermal failure in a high speed IC. Embodiments of the present invention are described below, by way of example only, with reference to FIGS. 1-8.

In very general terms, the present invention provides techniques in which the signal processing performed by an IC can be adjusted based on changes in the IC temperature. Thus, the present invention also provides a control circuit and method in which the temperature of the IC is detected, and the detected temperature used to generate a control signal used to adjust (either by reducing or increasing) the signal processing performed by the IC. If desired, the temperature may be detected at multiple locations within the IC, and the multiple temperature values used singly, for example to detect portions of the IC which may be generating most of the active heat load. Alternatively, the multiple temperature measurements may be combined, for example to obtain an average temperature of the IC. If desired, the rate of change of the IC temperature with time may be calculated and used. In any such case, specific devices for detecting the temperature of an IC, such as thermocouples or temperature-sensitive resistors, for example, are well known, and thus will not be described herein.

Various techniques may be used to process the detected temperature value(s) to generate one or more control signals. These may include comparing a detected temperature to a predetermined threshold. Thus, in the following examples, the processing performed by the IC is reduced if the detected temperature rises above a predetermined threshold. This predetermined threshold may correspond with a maximum permissible IC temperature, or alternatively may correspond with a selected temperature blow the maximum permissible, for example to provide a safety margin. It will be appreciated that the reverse-operation is also possible; that is, the processing performed by the IC may be increased (within the physical design constraints of the IC, of course) when the detected temperature is below the threshold. In some cases, it may be desirable to provide two thresholds, one representing a higher temperature than the other. Thus, for example, the processing performed by the IC can be reduced if the detected temperature rises above the first (higher) threshold, and is increased when the detected temperature drops below the second (lower) threshold. As may be appreciated, this operation tends to reduce rapidly changing the IC processing.

As will be appreciated, the design of control circuits capable of performing the above operations is well within the purview of those of ordinary skill in the art, and so do not require detailed explanation herein.

For the purposes of the present description the invention will be described by way of two embodiments, namely a Frequency-Domain Processor (FDP) and a Forward Error Correction (FEC) decoder, both of which may be implemented as IC components in a receiver. Those of ordinary skill in the art will recognise, however, that the present invention is by no means limited to these examples. It is expected that those of ordinary skill in the art will be able, based on the teachings of the present application, to apply the techniques to numerous other components in a high-capacity signal processing system.

### EXAMPLE 1

### Frequency-Domain Processor (FDP)

FIG. 1 illustrates principle elements of a coherent optical receiver of the type known from Applicant's co-pending U.S. patent applications Ser. No. 12/030,242 filed Feb. 13, 2008, in which methods in accordance with the present invention ay be implemented. As may be seen in FIG. 1, an inbound optical signal 4 received through an optical fiber link 6 is split into orthogonal received polarizations by a Polarization Beam Splitter 8. Both received polarisations are then mixed with a local oscillator (LO) signal 10 by a conventional 90° optical hybrid 12, and made incident on a set of photodetectors 14. The photodetector current output from each of the photodetectors 14 is then sampled by respective Analog-to-Digital (A/D) converters 16. The raw multi-bit digital sample streams I_{X}, Q_{X}, and I_{Y}, Q_{Y} generated by the A/D converters 16 are supplied to a signal equalizer 18. If desired, timing control methods described in Applicant's co-pending U.S. patent application Ser. No. 11/550,042 filed Oct. 17, 2006, including the use of elastic stores (not shown in FIG. 1) between the A/D converters 16 and the equalizer 18 may be used to ensure at least coarse phase alignment between samples at the equalizer input.

Each raw digital sample stream I_{X}, Q_{X}, and I_{Y}, Q_{Y} generated by the A/D converters 16 is composed of a series of multi-bit digital values. The resolution (in bits) of each sample stream is established by the design of the A/D converter circuit, and is selected based on a compromise between cost and the desired precision of the signal processing performed by the equalizer 18. In practice a resolution of between 6 and 8 bits has been found to be satisfactory.

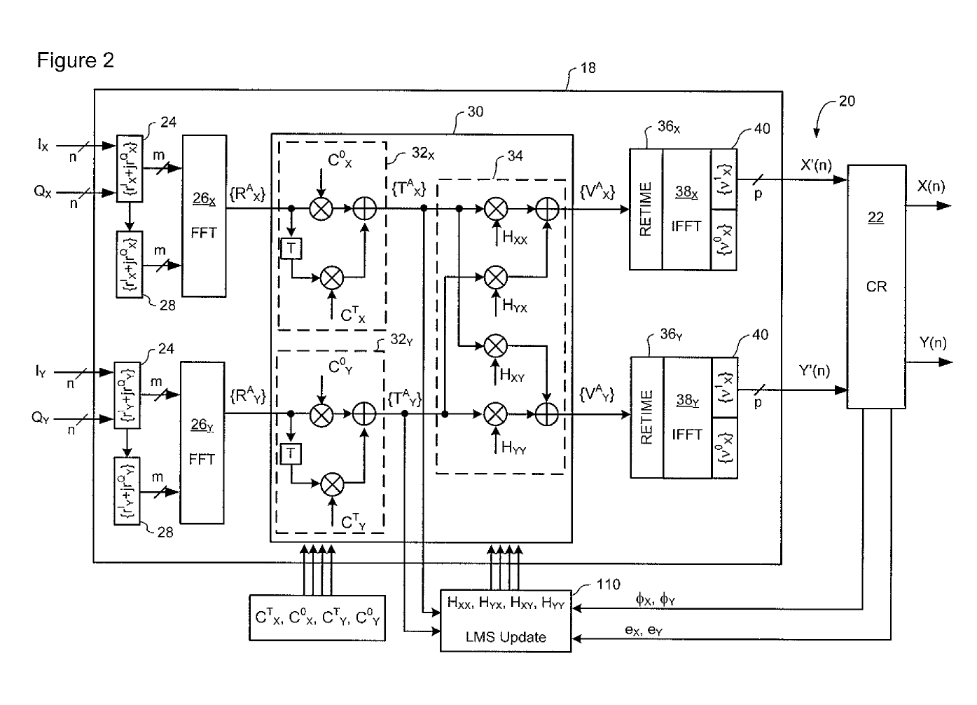

In general, the equalizer 18 operates to compensate chromatic dispersion and polarization rotation impairments. The compensated signals 20 output from the equalizer 18 represent multi-bit estimates X′ (n) and Y′ (n) of the symbols encoded on each transmitted polarization 34 of the received optical signal 4. The symbol estimates 20 X′ (n), Y′ (n), are supplied to a carrier recovery block 22 for LO frequency control, symbol detection and data recovery, such as described in Applicant's co-pending U.S. patent application Ser. No. 11/366,392 filed Mar. 2, 2006. FIG. 2 is a block diagram illustrating principle elements of a representative equalizer 18 useable in the receiver of FIG. 1.

In the embodiment of FIG. 2, the raw digital sample streams I_{X}, Q_{X}, and I_{Y}/Q_{Y} generated by the A/D converters 16 are deserialized (at 24) to form m-word input vectors {r^{I}_{X}+jr^{Q}_{X}} and {r^{I}_{Y}+jr^{Q}_{Y}} which span one half the width of the FFT. During each clock cycle, the m-word vectors {r^{I}_{X}+jr^{Q}_{X}} and {r^{I}_{Y}+jr^{Q}_{Y}} are latched into the respective X- and Y-polarization FFT blocks 26, along with the corresponding “old” vectors (at 28) from the previous clock cycle. Each FFT block 26 is a conventional complex FFT block having a width selected to enable compensation of the maximum anticipated chromatic dispersion of the received optical signal 4. In some embodiments, each FFT block 26 may have a width of 1024 taps, in which case m=512. The arrays {R^{A}X} and {R^{A}y} output by the FFT blocks 26 are then supplied to a Frequency Domain Processor (FDP) 30.

In the embodiment of FIG. 2, the FDP 30 comprises a respective transpose-and-add functional block 32 for each polarization, and a cross-compensation block 34. The transpose-and-add block 32 may operate in generally the same manner as described in Applicant's co-pending U.S. patent application Ser. No. 11/550,042 filed Oct. 17, 2006. Thus, the X-polarization transpose-and-add block 32x operates to add the FFT output array {R^{A}X} to a transposed (conjugate) version of itself { R̅_{X}^{A}}, with respective different compensation vectors {C⁰_{X}} and {C^{T}_{X}}, to yield intermediate array {T^{A}_{X}}. Compensation vectors {C⁰_{X}} and {C^{T}_{X}} can be computed using a transform of a 1^{st} order dispersive function to at least partially compensate chromatic dispersion of the optical link; and/or using empirical knowledge of propagation delays encountered in each signal path between the optical fiber 6 and the equalizer input to compensate residual sample phase errors in the raw digital signals generated by the A/D converters 16. Of course, the Y-polarization transpose-and-add block 32_{Y} will operate in an exactly analogous manner.

The cross-compensation block 34 applies x-polarization vectors H_{XX}, H_{XY} to the X-polarization intermediate array {T^{A}_{X}} and Y-polarization vectors H_{YY}, H_{YX} to the Y-polarization intermediate array {T^{A}_{Y}}. The multiplication results are then added together to generate modified vectors {V^{A}_{X}} and {V^{A}_{Y}}, as may be seen in FIG. 2. The X- and Y-polarization vectors H_{XX}, H_{XY}, H_{YY} and H_{YX} are preferably computed using a transform of the total distortion at the output of the equalizer 18, as will be described in greater detail below, At a minimum, the X- and Y-polarization vectors H_{XX}, H_{XY}, H_{YY} and H_{YX} impose a phase rotation which compensates polarization impairments of the optical signal, and so de-convolve the transmitted symbols from the raw digital sample streams I_{X}, Q_{X}, and I_{Y}, Q_{Y} generated by the A/D converters 48. Those of ordinary skill in the art will recognise that the illustrated cross-compensation block 34 implements an inverse-Jones matrix transfer function, which compensates the polarization effects. In this formulation, the vectors H_{XX}, H_{XY}, H_{YY} and H_{YX} are provided as the coefficients of the inverse-Jones matrix. The width of the inverse-Jones matrix is equal to that of the intermediate arrays {T^{A}_{X}} and {T^{A}_{Y}} and so is based on the expected maximum dispersion of the received optical signal to be compensated by the equalizer 18.

The modified arrays {V^{A}_{X}} and {V^{A}_{Y}} output by the FDP 30 are then supplied to respective retiming blocks 36, which operate to re-time the modified arrays {V^{A}_{X}} and {V^{A}_{Y}} from the sample timing of the A/D converters 16 to the desired T-spaced timing of the multi-bit symbol estimates 20.

By way of example only, consider an embodiment in which a 35 GBaud optical signal 4 is sampled at a sample rate of 1/T_{S}=40 GHz. The A/D converters 16, FFT blocks 26, and FDP 30 will all operate at the sample rate of 1/T_{S}=40 GHz. In this case, each of the arrays {R^{A}_{X}} and {R^{A}_{Y}} output by the FFT blocks 26, and thus each of the modified arrays {V^{A}_{X}} and {V^{A}_{Y}} output by the FDP 30 span a frequency range of 0-40 GHz, with upper side band (USB) spectrum at 0-20 GHz and lower side band (LSB) at 20-40 GHz, respectively. In principle, retiming of the modified arrays {V^{A}_{X}} and {V^{A}_{Y}} can be accomplished by extracting the center portion of each array, and then supplying the remaining portions to the IFFT blocks 38.

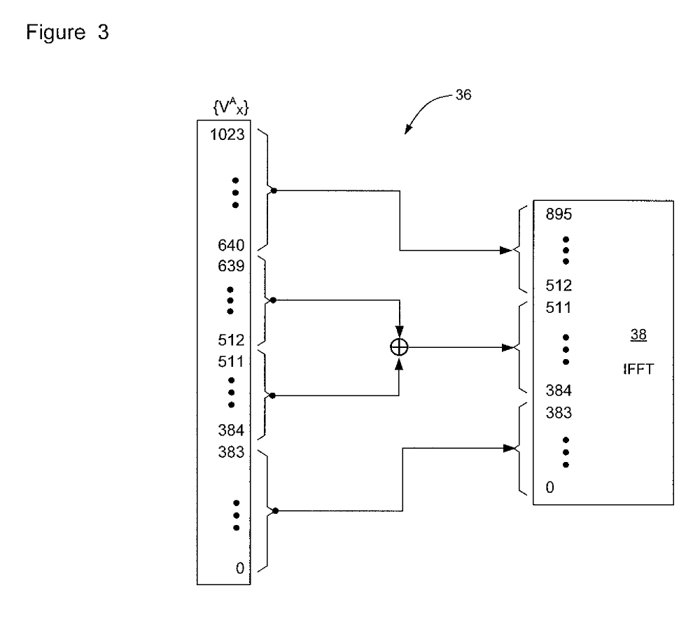

In an embodiment in which each FFT block 26 has a width of 1024 taps (that is taps n=0 . . . 1023), with USB at n=0-511 and LSB at n−512-1023, retiming the modified arrays {V^{A}_{X}} and {V^{A}_{Y}} can be accomplished by recognising that, within each array, the combined spectrum is nominally symmetrical about the center of the array. Consequently, the upper and lower halves of the array can be overlapped by a selected number of taps in the center portion of the array, and the thus “overlapped taps” added together. The number of overlapped taps is selected so that, after the addition operation, the total number of remaining taps corresponds with the desired width of the retimed array. In the above example, the 1024 taps of the FFT output spans a frequency range of 0-40 GHz, and it is desired to reduce the frequency range to 0-35 GHz. This corresponds with a reduction of 128 taps. Thus, the upper and lower halves of each modified array {V^{A}_{X}} and {V^{A}_{Y}} are overlapped by 128 taps and the overlapped taps added together. This results in the 128 taps lying above the center of the array (taps n=512 . . . 639) being added to the 128 taps lying below the center of the array (taps n=384 . . . 511), and the summation result supplied to taps 384-511 of the retimed array, as shown in FIG. 3. The taps lying above and below this center region (at taps 0-383 and 640-1023, respectively) are then supplied to corresponding upper and lower portions of the retimed array, again as shown in FIG. 3. This operation effectively removes 128 taps from the center of each of the modified arrays {V^{A}_{X}} and {V^{A}_{Y}} to yield retimed arrays {V^{A}_{X}}′ and {V^{A}_{Y}}′, in the form of complex multi-bit vectors having a width of 896 taps, and spanning a frequency range of 0-35 GHz.

The retimed arrays {V^{A}_{X}}′ and {V^{A}_{Y}}′ are then supplied to the IFFT blocks 38, which operate at the T-spaced symbol rate of 35 GHz to generate time domain data 40, in the form of a complex valued vector having a width equal to the IFFT 38, which, in the illustrated embodiment is N=896 taps. The IFFT output data 40 is divided into two blocks {v⁰_{X}}, and {v¹_{X}}, of which {v_{X}} is selected as the equalizer output 20 in the form of a complex valued vector {υ^{I}_{X}+jυ^{Q}_{X}} representing p=448 T-spaced complex valued estimates X′ (n) and Y′ (n) of the transmitted symbols. The other IFFT output block, {v⁰_{X}}, is discarded.

As may be appreciated, the amount of active heat generated by the FDP 30, for any given sample clock speed, is a function of the average number of gates exhibiting state transitions at any particular instant. Thus, it is possible to control the active heat generated by controlling this number. This can be accomplished by each of the following strategies, which can be used alone, or in any desired combination:

zero-out one or more least significant bits (LSBs) of the multi-bit samples generated by each A/D converter 16;

zero-out one or more LSBs of each tap of the FFT 26; and

reduce the impulse response width of the equalizer 18 (or, equivalently, FFT 26);

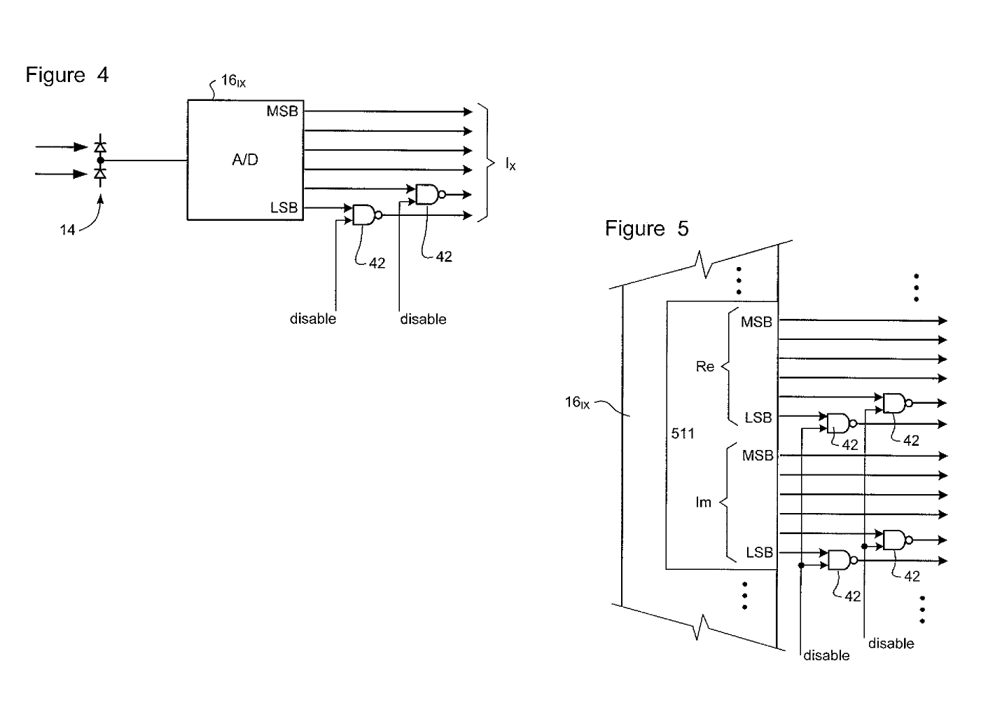

FIG. 4 schematically illustrates a representative technique for zeroing-out LSBs of the multi-bit samples generated by each A/D converter 16. In the embodiment of FIG. 4, each A/D converter 16 is constructed to generate 6-bit samples. A pair of logical NAND-gates 42 are coupled to receive the two least significant bits of the A/D converter output, and also receive respective “disable” signals from a controller (not shown). With this arrangement, the two LSBs of each sample stream can be selectively enabled or disabled, as desired. Thus for example, when the IC temperature is below a predetermined threshold, the two LSBs can be enabled, thereby allowing all 6 bits of each sample to propagate through to the equalizer 18. On the other hand, when the IC temperature rises above the threshold, the LSBs can be “disabled”, to force their value to zero. As may be appreciated, forcing LSB values to zero reduces the number of gates (primarily within the FFT 26, but also within the FDP 30) that will experience state transitions during processing of each of the m-word input vectors {r^{I}_{X}+jr^{Q}_{X}} and {r^{I}_{Y}+jr^{Q}_{y}}. As may be appreciated, using a separate “disable” signal to control each LSB allows the sample resolution to be progressively reduced as the temperature of the IC increases. For example, multiple threshold values may be defined. As the IC temperature rises above the first threshold, the first LSB of each sample is disabled; if the IC temperature continues to rise and exceeds a second threshold, then a further LSB may by disabled; and so on. Alternatively, a time-based approach may be used with a single threshold value. For example, if the IC temperature rises above the lowest LSB is disabled. IF, after a predetermined period of time, the IC temperature remains above the threshold, then the next lowest LSB is disabled.

A directly analogous approach can be used to zero-out one or more LSBs of each tap of the FFT 26. FIG. 5 schematically illustrates a representative example, showing tap No. 511 of the FFT 26. In the illustrated example, each of the real and imaginary parts of each complex tap value has a resolution of 6 bits. This may be referred to as “6+6 resolution”. A NAND-gate 42 is coupled to each of the two LSBs of each of the real and imaginary parts of the tap, and receives a respective “disable” signal from a controller (not shown). With this arrangement, the two LSBs of each part of the tap value can be selectively enabled or disabled, as described above with reference to FIG. 4. As may be appreciated, forcing the LSBs of each tap to zero reduces the number of gates within the FDP 30 that will experience state transitions during processing of the FFT output array {R^{A}_{X}}.

As will be appreciated, zeroing-out the LSBs of the A/D samples and/or the FFT output array {R^{A}_{X}} values will inherently reduce the precision of the equalizer 18, and so increase the error rate of the sample estimates 20. However, sufficiently robust Forward Error Correction (FEC), may be able to compensate the increased raw error rate.

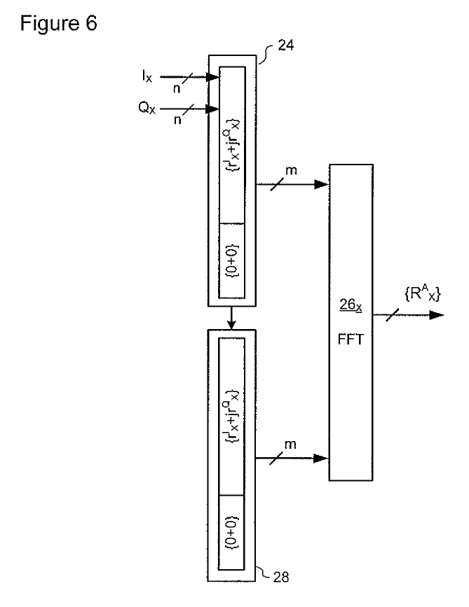

FIG. 6 illustrates a representative technique for varying the impulse response of the FFT 26. In this case, the length of each input vector {r^{I}_{X}+jr^{Q}_{X}} and {r^{I}_{Y}+jr^{Q}_{Y} } remains constant at m-words. However, the number of I,Q samples latched into each input vector during each clock cycle is adjusted, and the remaining (unused) words of the input vector filled (or “padded”) with zeros. In some embodiments, the duration of each clock cycle is adjusted in accordance with the reduced number of I,Q samples latched into the input vectors. For example, in an embodiment in which a “normal” clock cycle has a duration corresponding to 1024 I,Q samples, reducing the clock duration by 128 I,Q samples would result in input vectors {r^{I}_{X}+jr^{Q}_{X}} and {r^{I}_{Y}+jr^{Q}_{Y}} comprising 896 complex values and 128 words of padding. An advantage of this approach is that all of the samples generated by the A/D converters 16 are ultimately used, so no information of the sample streams is lost. However, reducing the number of non-zero samples loaded into each input vector (and padding the input vector with zeros) simplifies FFT computations required to generate the FFT output array {R^{A}_{X}}, and this yields a corresponding reduction in active heat generation.

### EXAMPLE 2

### Forward Error Correction (FEC) Decoder

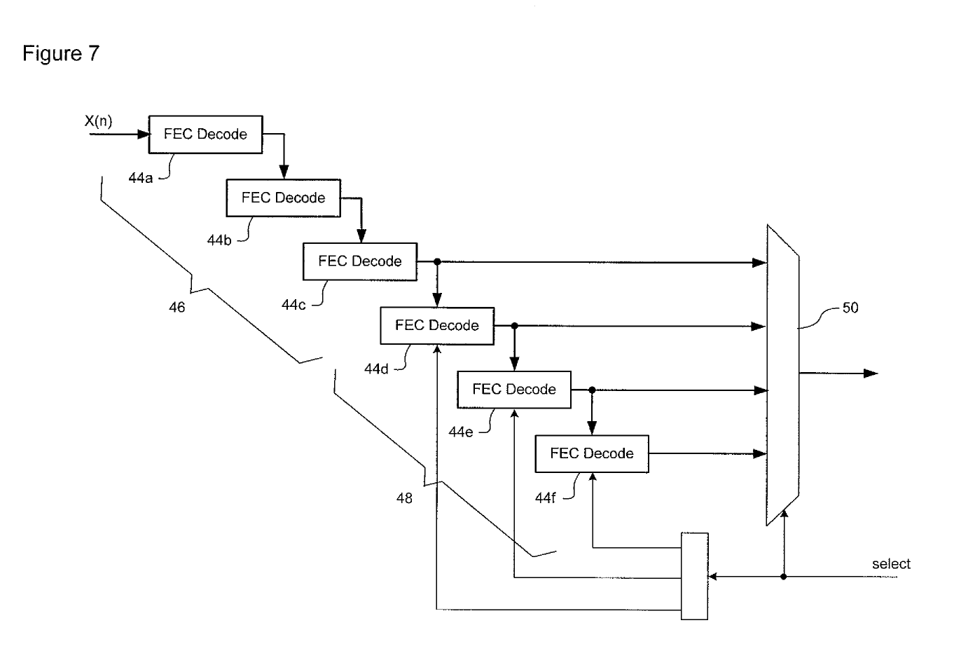

FIG. 7 schematically illustrates a representative technique by which Forward Error Correction (FEC) decoding can be adjusted based on changes in the IC temperature. In the embodiment of FIG. 7, the FEC decoding operation is represented by a cascade of FEC decode blocks 44a-f, which are cascaded to enable iterative decoding of sample estimates X(t) which may, for example, be supplied by the receiver described above with reference to FIGS. 1-6.

Iterative FEC decoding is known in the art. Normally, each iteration corrects some of the bit errors, and enables additional bit errors to be corrected by the next iteration. In the embodiment of FIG. 7, the conventional iterative FEC decode operation is modified to that the number of iterations that are performed can be adjusted during runtime. In the illustrated embodiment, the cascade of FEC decode blocks is divided into a first stage 46 and a second stage. The first stage (which, in the embodiment of FIG. 7 encompasses FEC decode blocks 44a-c) is cascaded in a conventional manner, and so defines the minimum number of iterations which are preformed. If desired, this minimum number of iterations may be selected based on expected “best case” conditions of the communications system, which would correspond to best-case raw bit error rates, and consequent lower need for FEC decoding.

The second stage 48 encompasses any desired number of additional FEC decode blocks and a selector block 50, which enables a desired number of additional FEC decode iterations to be performed. In the illustrated embodiment, the output of each FEC decode block 44 in the second stage 48 is supplied to both the next FEC decode block in the cascade, and to the selector block 50. A select signal supplied by a controller (not shown) can then be used to control the selector block 50 to route the output of a selected one of the FEC decode blocks to the output of the FEC decoder. The embodiment of FIG. 7 is therefore able to control the number of FEC decode iterations that are performed.

As may be seen in FIG. 7, the select signal may also be used to disable any FEC decode blocks that are not used. Thus, in the illustrated example, the second stage comprises a cascade of three FEC decode blocks. If only the first two of these is used (meaning that a total of five FEC decode iterations are performed), the remaining FEC decode block 44f can be disabled so that it does not generate any active heat.

For example, consider a communications system that uses an iteratively decoded product code. As is well known in the art, each error that is corrected in any given iteration tends to allow other errors to be corrected in later iterations. Such a method can convert a raw error rate of 0.3% to better than 1×10⁻¹² after ten iterations.

Further consider a FEC decoder IC in which, under worst case conditions, a junction temperature of 100° C. is obtained at a power dissipation of 20 Watts power dissipation. If the Input/Output (IO) heat of the IC is 5 Watts and the static heat is 5 Watts, then the “power budget” for active heat is 10 Watts. If each FEC decode iteration produces 2 watts of active heat, then a maximum of five FEC decode iterations can be performed.

However, under optimum conditions (e.g. the decoder is operating at sea level, fans are operating to blow cool air over the IC, the device fabrication achieves typical parameters, and the battery voltage is nominal), the same FEC decode chip may achieve a junction temperature of only 65° C. at 20 Watts. If each iteration (2 Watts of active heat) raises the junction temperature by 4° C., then there is room for 8 more iterations (for a total of 13 iterations) before the thermal limit of 100° C. is reached.

With a temperature sensor on the chip, an on-chip controller can determine the current junction temperature, and adjust the number of iterations (in real-time) so as to maximize the number of iterations performed while at the same time keeping the junction temperature below the maximum permitted value.

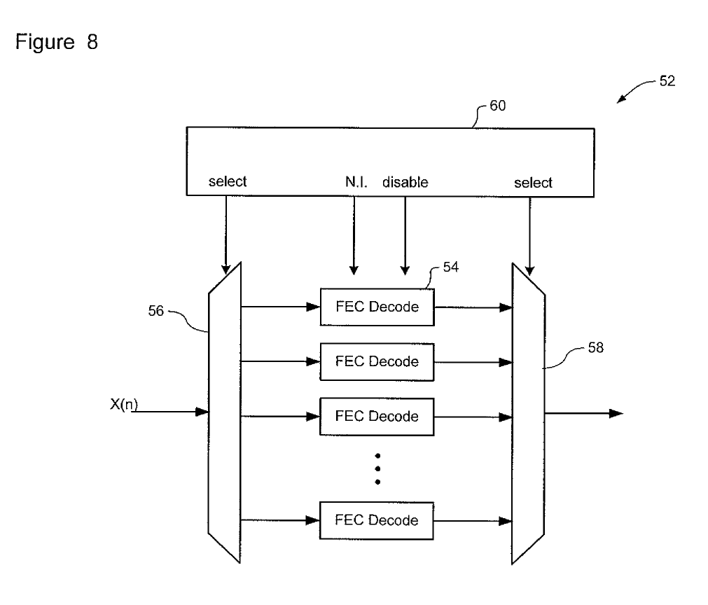

FIG. 8 schematically illustrates a related technique by which Forward Error Correction (FEC) decoding can be adjusted based on changes in the IC temperature. In the embodiment of FIG. 8, a FEC decoder 52 comprises a plurality of FEC decode blocks 54 connected in parallel between an input switch block 56 and an output switch block 58. A controller unit 60 controls the input and output switch blocks 56 and 58, and each of the FEC blocks 54, as will be described in greater detail below. Each FEC decode block 54 is designed to execute a desired number of FEC decode iterations, which can be adjusted by means of a control signal received from the control unit 60. In operation, the controller unit 60 controls the input switch block 56 to route successive data blocks (comprising a predetermined number of bits) to selected ones of the parallel FEC decode blocks 54. Typically, the FEC decode blocks 54 will be selected sequentially, so that each FEC decode block 54 has the same amount of time to complete its FEC iterations. The output of each FEC decode block 54 is selected in a similar manner, so that processed symbols are read from each FEC decode block 54 and output from the decoder 52 in the correct order.

The active heat generated by the FEC decoder 52 of FIG. 8, for any given symbol rate, will be proportional to the number of active FEC decode blocks 54. Accordingly, the active heat an be controlled during runtime, by selectively enabling/disabling one or more of the FEC decode blocks 54. In order to avoid data loss, this operation requires a corresponding adjustment of the number of FEC iterations performed by each FEC decode block 54. For example, consider an embodiment comprising a total of N=8 parallel FEC decode blocks 54. When all eight FEC decode blocks 54 are active, each decode block 54 receives and processes a data block during a processing period that encompasses N=8 clock cycles, of which about 7 cycles are available for computing FEC iterations. Assume, for the purposes of the present discussion, that a maximum of M=12 iterations can be completed during this time.

If one of the FEC decode blocks 54 is disabled, for example by means of a disable signal from the controller 60, then the number of active FEC decode blocks 54 is n=7, and the time available for computing FEC iterations is reduced to approximately n-1=6 clock cycles. The total number of FEC iterations that can be completed during this period will be

$$m = INT [ \frac{M}{( N - 1 )} x ( n - 1 ) ] = 10.$$

If a second FEC decode block 54 is disabled, then the period for completing FEC iterations will be further reduced, and the total number of FEC iterations that can be completed during this period will be m=8. Accordingly, as the number of active FEC decode blocks 54 is reduced, the total number of FEC iterations performed by each of the remaining active FEC decode blocks must be reduced proportionately, so as to ensure that the FEC iterations will be completed before the next data block arrives.

With a temperature sensor on the chip, an on-chip controller 60 can determine the current junction temperature, and adjust the number of active FEC decode blocks 54 (and thus the number of FEC iterations performed by each active FEC decode block), in real-time, so as to maximize the number of active FEC decode blocks (and the number of FEC iterations) performed while at the same time keeping the junction temperature below the maximum permitted value.

In the foregoing description, junction temperatures are determined by means of an on-chip temperature sensor. However, this is not essential. Other means of estimating junction temperature may be used. For example, a temperature sensor could be located in the environment of the chip, but separate from the chip, such as on a heat sink or in a cooling air inlet or exhaust stream. Either contact (e.g. resistive) or non-contact (e.g. Infra-red) sensors may be used. Parameters other than temperature can be used to deduce the IC temperature, such as supply voltage, supply current, power, air velocity, air pressure, fan failure, IC circuit parameter, temperature differential, bit or frame error count, iteration count, or application dependent provisioning.

The embodiments of the invention described above are intended to be illustrative only. The scope of the invention is therefore intended to be limited solely by the scope of the appended claims.

We claim:

1. A method of managing operation of an Integrated Circuit (IC) designed to process a signal, the method comprising:
detecting a temperature of the IC; and
adjusting signal processing performed by the IC based on the detected temperature.

2. The method of claim 1, wherein the step of adjusting signal processing performed by the IC comprises:
comparing the detected temperature to a predetermined threshold; and
adjusting signal processing performed by the IC based on the comparison result.

3. The method of claim 2, wherein the predetermined threshold corresponds with a maximum permissible temperature of the IC.

4. The method of claim 2, wherein the predetermined threshold is a predetermined temperature below a maximum permissible temperature of the IC.

5. The method of claim 2, wherein the step of adjusting signal processing performed by the IC comprises:
reducing the signal processing when the detected IC temperature is above the threshold; and
increasing the signal processing when the detected IC temperature is below the threshold.

6. The method of claim 5, wherein first and second threshold values are provided, the first threshold representing a higher IC temperature than the second threshold, and wherein the step of adjusting signal processing performed by the IC comprises:
reducing the signal processing when the detected IC temperature is above the first threshold; and
increasing the signal processing when the detected IC temperature is below the second threshold.

7. The method of claim 5, wherein adjusting the signal processing comprises selectively enabling or disabling one or more Least Significant Bits (LSBs) of multi-bit sample values processed by the IC.

8. The method of claim 7, wherein the multi-bit sample values are sample values generated by an Analog-to-Digital (A/D) converter.

9. The method of claim 7, wherein the multi-bit sample values are tap values calculated by a Fast Fourier Transform (FFT) block.

10. The method of claim 5, wherein adjusting the signal processing comprises selectively adjusting an impulse response of an equalizer of the IC.

11. The method of claim 5, wherein selectively adjusting an impulse response of an equalizer of the IC comprises adjusting an width of an input vector input to the equalizer.

12. The method of claim 5, wherein adjusting the signal processing comprises controlling a number of iterations of an iterative computation performed by the IC.

13. The method of claim 5, wherein adjusting the signal processing comprises controlling a number of active parallel instances of a parallel computation performed by the IC.

14. The method of claim 1, where determining a temperature of the IC comprises the step of determining a physical characteristic in the environment of the IC

15. The method of claim 14, where the physical characteristic is a temperature of an element separate from the IC.

16. The method of claim 1, where determining a temperature of the IC comprises the step of measuring a characteristic that is temperature dependent.
